(19) United States
(12) Patent Application Publication
(10) Pub. No.: US 2017/0062615 A1
(43) Pub. Date: Mar. 2, 2017

(54) METHOD OF FORMING SEMICONDUCTOR DEVICE

(71) Applicant: United Microelectronics Corp., Hsinchu (TW)

(72) Inventors: Ying-Chiao Wang, Changhua County (TW); Ssu-I Fu, Kaohsiung City (TW); Jyh-Shyang Jenq, Pingtung (TW); Hon-Huei Liu, Kaohsiung City (TW); Yu-Hsiang Hung, Tainan City (TW)

(21) Appl. No.: 14/837,781

(22) Filed: Aug. 27, 2015

(51) Int. Cl. H01L 29/78; H01L 29/16; H01L 29/165; H01L 29/24; H01L 29/167; H01L 21/8238; H01L 29/161

(52) U.S. Cl. CPC H01L 29/7848; H01L 21/823821; H01L 21/823807; H01L 21/823814; H01L 21/823864; H01L 29/1608; H01L 29/161; H01L 29/24; H01L 29/167; H01L 29/165

(57) ABSTRACT

A method of forming a semiconductor device is disclosed. A substrate having a first area and a second area is provided. A first doped layer containing a first type of dopant is formed on the substrate only in the first area. A second doped layer containing a second type of dopant is formed on the substrate only in the second area. An annealing step is performed to drive the first type of dopant and the second type of dopant into the substrate.

### FIELD OF THE PRESENT INVENTION

The present invention relates to an integrated circuit fabrication, and particularly to a method of forming a semiconductor device.

### DESCRIPTION OF RELATED ART

In the field of integrated circuit devices, the device dimensions are often reduced to attain a higher operating speed and a lower power consumption. However, with the ever-increasing level of integration of devices, the miniaturization of devices has almost reached its limit.

In recent years, a multi-gate structure such as a fin field effect transistor (FinFET) device is proposed to overcome the limitations imposed by the device miniaturization. Besides, strain engineering such as controlling the stress in the channel region of a transistor is also adopted. In the conventional method, source/drain regions are usually formed in epitaxial layers with an ion implantation process. However, such ion implantation may cause lattice disorder and dislocation, and thus, the epitaxial strain may be relaxed and the electronic performance of the device may be decreased.

SUMMARY OF THE PRESENT INVENTION

Accordingly, the present invention provides a method of forming a semiconductor structure, in which a solid state doping (SSD) process is adopted to solve the implantation-induced lattice distortion or damage and therefore improve the device of the performance.

The present invention further provides a method of forming a semiconductor device. A substrate having a first area and a second area is provided. A first doped layer containing a first type of dopant is formed on the substrate only in the first area. A second doped layer containing a second type of dopant is formed on the substrate only in the second area. An annealing step is performed to drive the first type of dopant and the second type of dopant into the substrate.

According to an embodiment of the present invention, the step of forming the first doped layer includes forming a first doped material layer containing the first type of dopant on the substrate in the first and second areas, forming a first mask material layer on the first doped material layer, and removing the first mask material layer and the first doped material layer in the second area.

According to an embodiment of the present invention, the step of removing the first mask material layer and the first doped material layer in the second area includes performing first photolithography etching processes.

According to an embodiment of the present invention, the first mask material layer includes silicon nitride (SiN), silicon carbonitride (SiCN), silicon oxynitride (SiON), silicon carbide (SiC), silicon oxycarbide (SiOC), carbon doped silicon oxynitride (SiOCN) or a combination thereof.

According to an embodiment of the present invention, the step of forming the second doped layer includes forming a second doped material layer containing the second type of dopant on the substrate in the first and second areas, forming a second mask material layer on the second doped material layer, and removing the second mask material layer and the second doped material layer in the first area.

According to an embodiment of the present invention, the step of removing the second mask material layer and the second doped material layer includes performing second photolithography etching processes.

According to an embodiment of the present invention, the second mask material layer includes SiN, SiCN, SiON, SiC, SiOC, SiOCN or a combination thereof

According to an embodiment of the present invention, the method further includes removing the first and second doped layers simultaneously after the annealing step.

According to an embodiment of the present invention, the first and second doped layers are defined with lightly doped drain (LDD) photomasks.

According to an embodiment of the present invention, the first and second doped layers have substantially the same thickness.

According to an embodiment of the present invention, the substrate further has first and second gate structures respectively formed in the first and second areas, and the first and second doped layers respectively cover the first and second gate structures.

According to an embodiment of the present invention, the substrate is a substrate having multiple fins extending in a first direction, and the first and second gate structures extend in a second direction different from the first direction.

According to an embodiment of the present invention, the substrate is a bulk substrate.

According to an embodiment of the present invention, the annealing step drives the first type of dopant into first epitaxial layers in the first area and simultaneously drives the second type of dopant into second epitaxial layers in the second area.

According to an embodiment of the present invention, the first epitaxial layers include silicon phosphide (SiP) or silicon carbide (SiC), and the second epitaxial layers include silicon germanium (SiGe).

According to an embodiment of the present invention, the first epitaxial layers include SiGe, and the second epitaxial layers include SiP or SiC.

According to an embodiment of the present invention, the first doped layer includes phosphosilicate glass (PSG) or arsenosilicate glass (ASG), and the second doped layer includes borophosphosilicate glass (BPSG).

According to an embodiment of the present invention, the first doped layer includes BPSG, and the second doped layer includes PSG or ASG.

According to an embodiment of the present invention, the first area is an N-type device area and the second area is a P-type device area.

According to an embodiment of the present invention, the first area is a P-type device area and the second area is an N-type device area.

In view of the above, in the present invention, the dopant providing layers can be defined through the existing LDD photomasks without an additional cost, and a single annealing step is performed to drive the dopants into the underlying epitaxial layers. After the drive-in annealing step, the dopant providing layers can be removed simultaneously without leaving any etching residue. With the method of the invention, the conventional implantation-induced defects and etching residues are not observed, and the performance of the device is accordingly improved.

Several exemplary embodiments accompanied with figures are described in detail below to further describe the present invention in details.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1I are schematic cross-sectional views illustrating a method of forming a semiconductor device according to an embodiment of the present invention.

### DETAILED DESCRIPTION OF DISCLOSED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

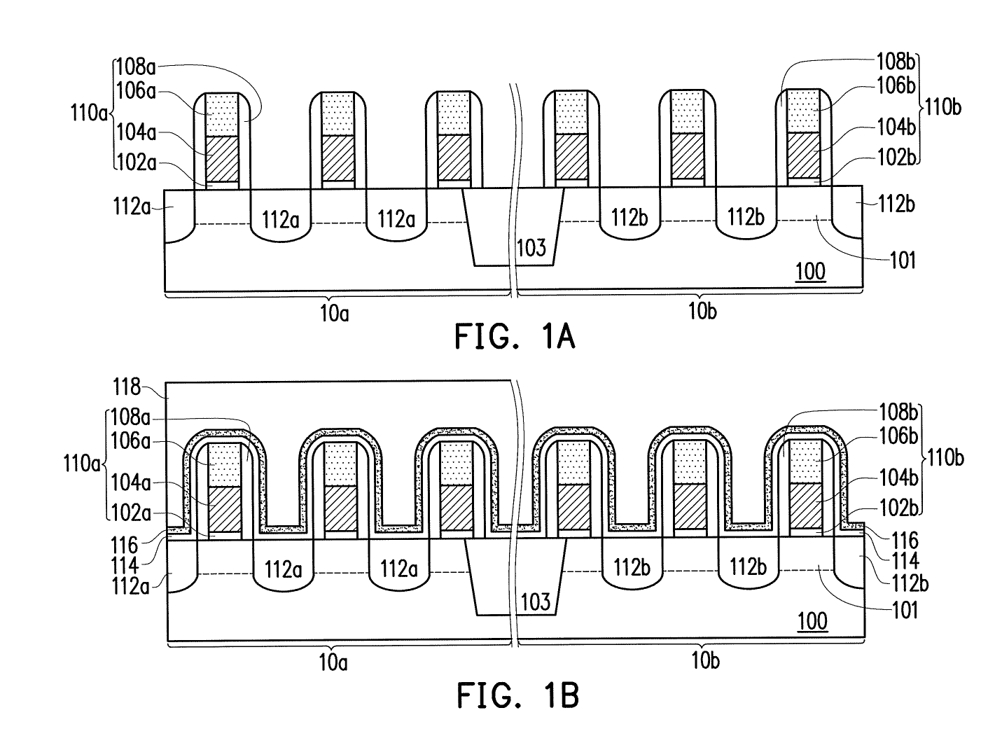

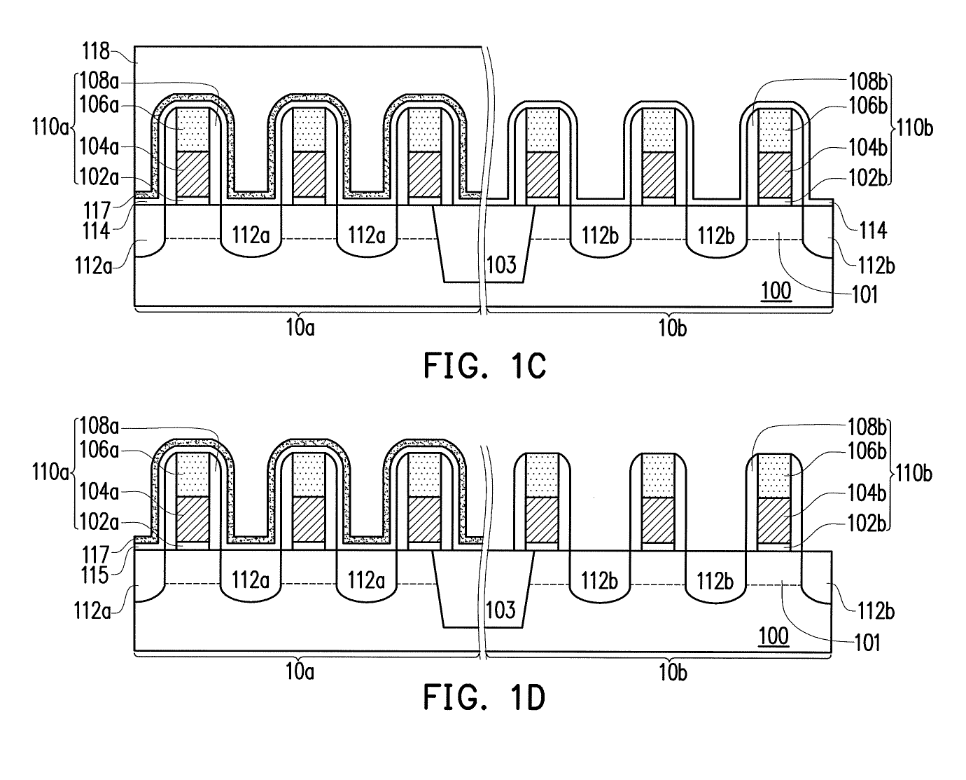

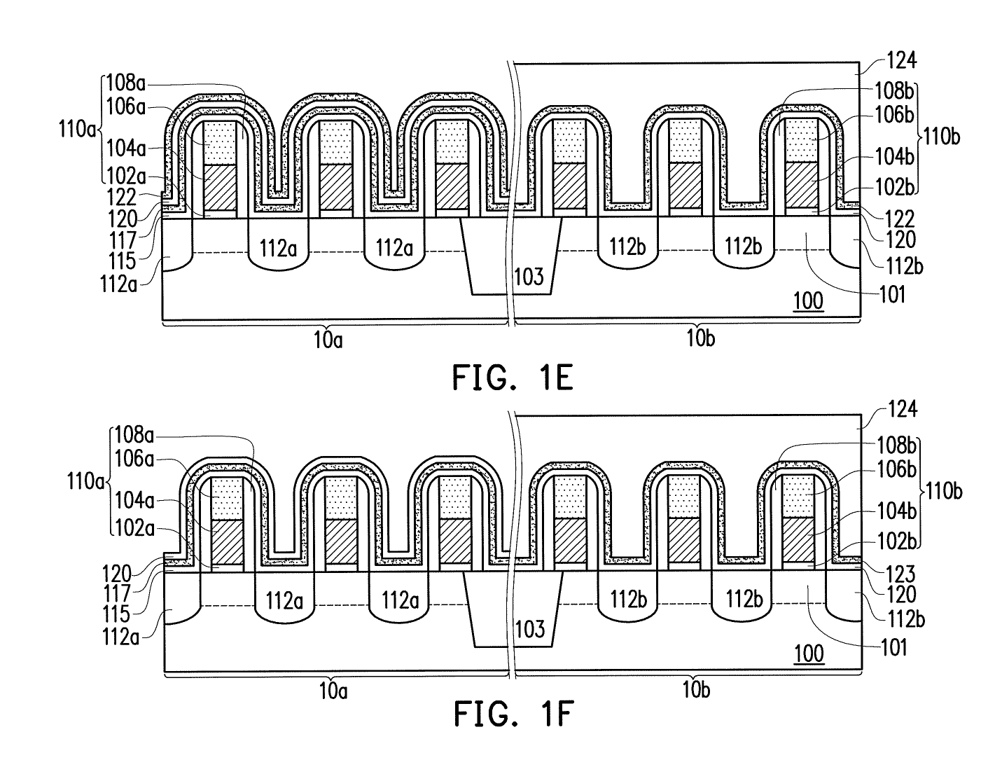

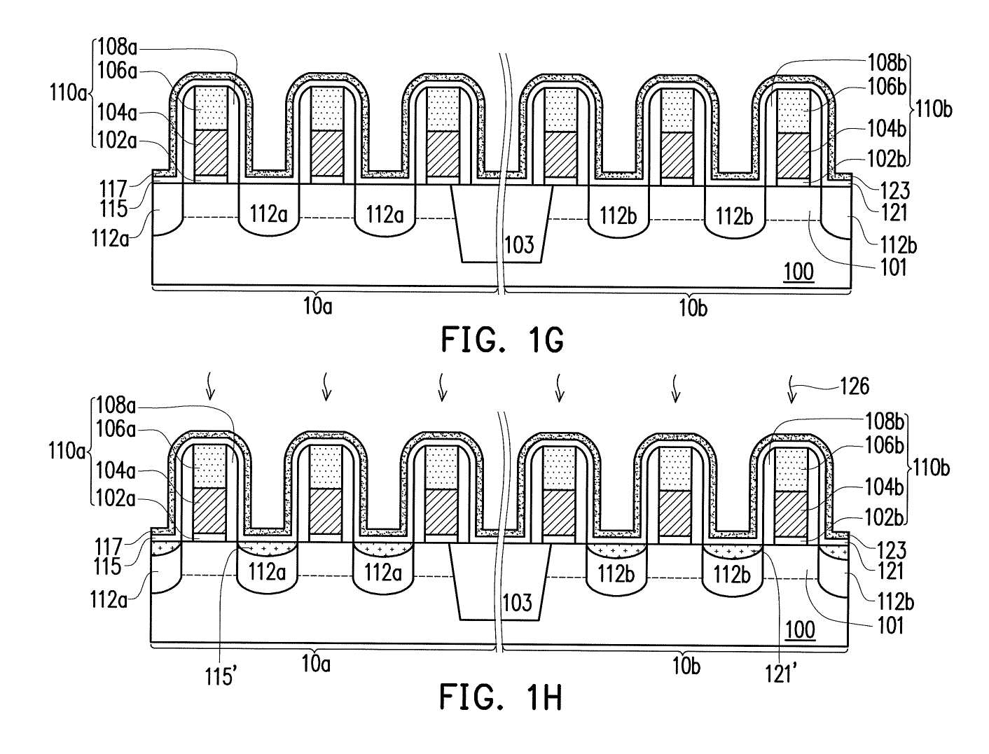

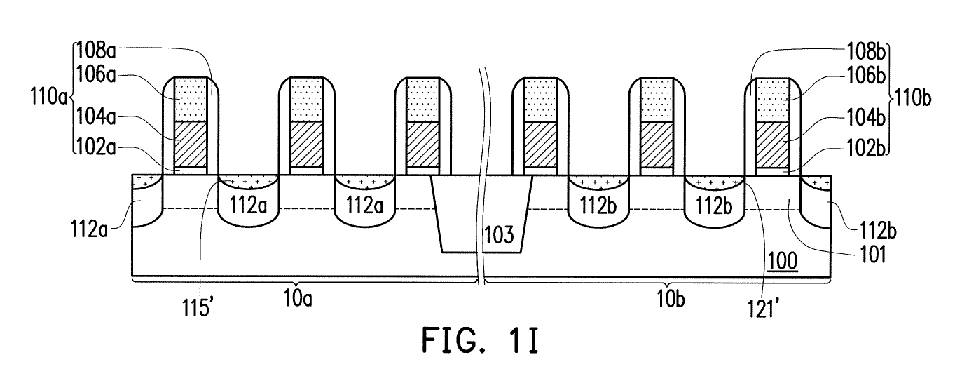

FIG. 1A to FIG. 1I are schematic cross-sectional views illustrating a method of forming a semiconductor device according to an embodiment of the invention.

Referring to FIG. 1A, a substrate 100 is provided. The substrate 100 can be a semiconductor substrate, such as a silicon-containing substrate. The substrate 100 has a first area 10a and a second area 10b. In an embodiment, the first area 10a is an N-type device area, and the second area 10b is a P-type device area. In another embodiment, the first area 10a is a P-type device area, and the second area 10b is an N-type device area. In an embodiment, an isolation structure 103 such as a shallow trench isolation (STI) structure is formed in the substrate 100 between the first and second areas 10a and 10b.

In an embodiment, the substrate 100 further has first and second gate structures 110a and 110b respectively formed in the first and second areas 10a and 10b. In an embodiment, the substrate 100 can a substrate with multiple fins 101 extending in a first direction, and the first and second gate structures 110a and 110b cross the fins 101 and extend in a second direction different from the first direction. For example, the second direction is perpendicular to the first direction.

In an embodiment, each first gate structure 110a include a first interfacial layer 102a, a first gate 104a and a first cap layer 106a sequentially formed on the substrate 100 and a first spacer 108a formed beside the first gate 104a. Similarly, each second gate structure 110b include a second interfacial layer 102b, a second gate 104b and a second cap layer 106b sequentially formed on the substrate 100 and a second spacer 108b formed beside the second gate 104b.

In an embodiment, each of the first and second interfacial layers 102a and 102b includes silicon oxide, silicon oxynitirde (SiON), a high-k material with a dielectric constant greater than 4 or a combination thereof. The high-k material can be metal oxide, such as rare earth metal oxide. The high-k material can be selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate, (SrBi₂Ta₂O₉, SBT), lead zirconate titanate (PbZrₓTi₁₋ₓO₃, PZT), and barium strontium titanate (BaₓSr₁₋ₓTiO₃, BST), wherein x is between 0 and 1. Each of the first and second gates 104a and 104b includes a silicon-containing material such as amorphous silicon, polysilicon or a combination thereof. Each of the first and second cap layers 106a and 106b includes silicon oxide, silicon nitride (SiN) or a combination thereof Each of the first and second spacers 108a and 108b includes SiN, SiCN or a combination thereof.

The embodiment of FIG. 1A in which each of the interfacial layers, the cap layers and the spacers is illustrated as a single layer is provided for illustration purposes and is not construed as limiting the invention. It is appreciated by people having ordinary skill in the art that each of the said elements can be a composite layer or a multi-layer structure upon the process requirements.

In an embodiment, the substrate 100 further has first and second epitaxial layers 112a and 112b formed in the substrate 100 respectively in the first and second areas 10a and 10b. Specifically, one first epitaxial layer 112a is formed between two adjacent first gate structures 110a, and one second epitaxial layer 112b is formed between two adjacent second gate structures 110b. The method of forming the first and second epitaxial layers 112a and 112b includes forming recesses in the substrate 100 in the first and second areas 10a and 10b and performing at least one selective epitaxy growth (SEG) process. In an embodiment, when the first area 10a is an N-type area and the second area 10b is a P-type area, the first epitaxial layers 112a include silicon phosphide (SiP) or silicon carbide (SiC), and the second epitaxial layers 112b include silicon germanium (SiGe). In another embodiment, when the first area 10a is a P-type area and the second area 10b is an N-type area, the first epitaxial layers 112a include SiGe, and the second epitaxial layers 112b include SiP or SiC.

Referring to FIG. 1B, a first doped material layer 114 containing a first type of dopant is formed on the substrate 100 in the first and second areas 10a and 10b, covering the first and second gate structures 110a and 110b. The first doped material layer 114 can be referred to as a first dopant providing layer including an insulating material and/or a semiconductor material doped with a first dopant. The method of forming the first doped material layer 114 includes performing a suitable deposition process such as chemical vapor deposition (CVD) or atomic layer deposition (ALD). Another forming method such as spin-coating, evaporation, reactive sputtering, chemical solution deposition or the like may also be employed. In an embodiment, when the first area 10a is an N-type area, the first doped material layer 114 includes phosphosilicate glass (PSG) or arsenosilicate glass (ASG). In another embodiment, when the first area 10a is a P-type area, the first doped material layer 114 includes borophosphosilicate glass (BPSG).

Thereafter, a first mask material layer 116 is formed on the first doped material layer 114 in the first and second areas 10a and 10b. The method of forming the first mask material layer 116 includes performing a suitable deposition process such as CVD or ALD. In an embodiment, the first mask material layer 116 includes a dielectric material that can be etched selectively with respect to the underlying first doped material layer 114. For example, the first mask material layer 116 includes a nitride-based or carbon-based material, while the first doped material layer 114 includes an oxide-based or silicon-based material. In an embodiment, the first mask material layer 116 includes silicon nitride (SiN), silicon carbonitride (SiCN), silicon oxynitride (SiON), silicon carbide (SiC), silicon oxycarbide (SiOC), carbon doped silicon oxynitride (SiOCN) or a combination thereof.

Referring to FIG. 1B to FIG. 1D, a first patterning step is performed to remove the first mask material layer 116 and the first doped material layer 114 in the second area 10b, and thus, a first mask layer 117 and a first doped layer 115 are formed on the substrate 100 only in the first area 10a. In an embodiment, the first patterning step includes performing first photolithography etching processes. In an embodiment, the first doped layer 115 physically contacts the surfaces of the first epitaxial layers 112a, as shown in FIG. 1D, but the invention is not limited thereto. In another embodiment, a buffer layer such as amorphous silicon is formed between the first doped layer 115 and each of the first epitaxial layers 112a.

In an embodiment, a first photoresist layer 118 is formed on the first mask material layer 116 in the first area 10a, as shown in FIG. 1B. Specifically, the first photoresist layer 118 covers the first mask material layer 116 in the first area 10a while exposes the first mask material layer 116 in the second area 10b. The first photoresist layer 118 is defined by a first photomask. In an embodiment, the first photoresist layer 118 includes a first bottom anti-reflection coating (BARC) and a first photosensitive material. Thereafter, a portion of the first mask material layer 116 is removed by using the first photoresist layer 118 as a mask, so as to fat n a first mask layer 117 in the first area 10a, as shown in FIG. 1C. The partial removal step of the first mask material layer 116 includes a dry etching process. The first photoresist layer 118 is then removed. Afterwards, a portion of the first doped material layer 114 is removed by using the first mask layer 117 as a mask, so as to form a first doped layer 115 underlying the first mask layer 117 in the first area 10a, as shown in FIG. 1D. The partial removal step of the first doped material layer 114 includes a dry etching process or a wet etching process (e.g., a H₃PO₄ solution).

Referring to FIG. 1E, a second doped material layer 120 containing a second type of dopant is foil led on the substrate 100 in the first and second areas 10a and 10b. Specifically, the second doped material layer 120 covers the first mask layer 117 in the first area 10a and covers the second gate structures 110b in the second area 10b. The second doped material layer 120 can be referred to as a second dopant providing layer including an insulating material and/or a semiconductor material doped with a second dopant different from the first dopant. The method of forming the second doped material layer 120 includes performing a suitable deposition process such as CVD or ALD. Another forming method such as spin-coating, evaporation, reactive sputtering, chemical solution deposition or the like may also be employed. In an embodiment, the second doped material layer 120 includes a dielectric material having an etching selectivity different from that of the first mask layer 117 but similar to that of the first doped layer 115. In an embodiment, when the second area 10b is a P-type area, the second doped material layer 120 includes BPSG. In another embodiment, when the second area 10b is an N-type area, the second doped material layer 120 includes PSG or ASG.

Thereafter, a second mask material layer 122 is formed on the second doped material layer 120 in the first and second areas 10a and 10b. The method of forming the second mask material layer 122 includes performing a suitable deposition process such as CVD or ALD. In an embodiment, the second mask material layer 122 includes a dielectric material that can be etched selectively with respect to the underlying second doped material layer 120. For example, the second mask material layer 122 includes a nitride-based or carbon-based material, while the second doped material layer 120 includes an oxide-based or silicon-based material. In an embodiment, the first and second mask material layers 116 and 122 include the same material, but the present invention is not limited thereto. In another embodiment, the first and second mask material layers 116 and 122 include different materials but exhibit similar etching selectivity. In an embodiment, the second mask material layer 122 includes SiN, SiCN, SiON, SiC, SiOC, SiOCN or a combination thereof.

Referring to FIG. 1E to FIG. 1G, a second patterning step is performed to remove the second mask material layer 122 and the second doped material layer 120 in the first area 10a, and thus, a second mask layer 123 and a second doped layer 121 are formed on the substrate 100 only in the second area 10b. In an embodiment, the second patterning step includes performing second photolithography etching processes. In an embodiment, the second doped layer 121 physically contacts the surfaces of the second epitaxial layers 112b, as shown in FIG. 1G. In another embodiment, a buffer layer such as amorphous silicon is formed between the second doped layer 121 and each of the second epitaxial layers 112b.

In an embodiment, a second photoresist layer 124 is formed on the second mask material layer 122 in the second area 10b, as shown in FIG. 1E. Specifically, the second photoresist layer 124 covers the second mask material layer 122 in the second area 10b while exposes the second mask material layer 122 in the first area 10a. The second photoresist layer 124 is defined by a second photomask. In an embodiment, the second photoresist layer 124 includes a second BARC and a second photosensitive material. Thereafter, a portion of the second mask material layer 122 is removed by using the second photoresist layer 124 as a mask, so as to form a second mask layer 123 in the second area 10b, as shown in FIG. 1F. The partial removal step of the second mask material layer 122 includes a dry etching process or a wet etching process (e.g., a H₃PO₄ solution). The second photoresist layer 124 is then removed. Afterwards, a portion of the second doped material layer 120 is removed by using the second mask layer 123 as a mask, so as to form a second doped layer 121 underlying the second mask layer 123 in the second area 10b, as shown in FIG. 1G. The partial removal step of the second doped material layer 120 includes a dry etching process.

In view of the above, the first and second doped layers 115 and 121 are formed on the substrate 100 respectively in the first and second areas 10a and 10b without overlapping with each other. In an embodiment, the first and second doped layers 115 and 121 have substantially the same thickness. In another embodiment, the first and second doped layers 115 and 121 have different thicknesses but exhibit similar etching selectivity.

In an embodiment, the first and second doped layers 115 and 121 are defined with lightly doped drain (LDD) photomasks. Specifically, the first photomask for defining the first photoresist layer 118 and therefore the first doped layer 115 can be the photomask for defining lightly doped regions in the second area 10b, and the second photomask for defining the second photoresist layer 124 and therefore the second doped layer 121 can be the photomask for defining lightly doped regions in the first area 10a. In such case, no additional photomask is required to define the first and second doped layers 115 and 121, so the process cost is saved.

Referring to FIG. 1H, an annealing step 126 is performed to drive the first type of dopant and the second type of dopant into the substrate 100. In an embodiment, the annealing step 126 drives the first type of dopant from the first doped layer 115 into the first epitaxial layers 112a and simultaneously drives the second type of dopant from the second doped layer 121 into the second epitaxial layers 112b, and thus, first doped regions 115′ are formed respectively in the first epitaxial layers 112a and second doped regions 121′ are formed respectively in the second epitaxial layers 112b. In an embodiment, the first doped regions 115′ serve as source/drain regions of the device in the first area 10a, and the second doped regions 121′ serve as source/drain regions of the device in the second area 10b.

Referring to FIG. 11, the first and second mask layers 117 and 123 are simultaneously removed through etching such as a dry etching process. Thereafter, the first and second doped layers 115 and 121 are simultaneously removed through etching such as a dry etching process.

It is noted that in the present invention, after the solid state doping (SSD) process as shown in FIG. 1A to FIG. 1H, the numbers of layers to be removed in the first and second areas 10a and 10b are the same, so the loading effect in the said etching steps in FIG. 11 are significantly reduced. That is, the layers in the first and second areas 10a and 10b can be removed easily without leaving an etching residue.

In an embodiment, the first and second mask layers 117 and 123 have the same material with substantially equal thickness, and the first doped layer 115 is provided with a film thicknesses and/or an etching selectivity similar to that of the second doped layer 121. By such manner, the loading effect during the said etching steps is negligible, so the conventional etching residues caused by different numbers of layers in the first and second areas can be avoided.

In an embodiment, the following process steps after forming the first and second doped regions 115′ and 121′ include forming a dielectric layer which exposes tops of the first and second gate structures 110a and 110b on the substrate 100, removing the first and second cap layers 106a and 106b and the first and second gates 104a and 104b to form first and second openings in the dielectric layer respectively in the first and second areas 10a and 10b, and filling first and second composite metal layers with different work functions respectively in the first and second openings. These steps are well-known to persons having ordinary skill in the art and are not iterated herein.

The said embodiment in which the described method is applied to form source/drain regions of a FinFET device is provided for illustration purposes, and is not construed as limiting the present invention. It is appreciated by people having ordinary skill in the art that the described method can be applied to form source/drain regions of a planar device. In an embodiment, when the method of the invention is applied to a planar device, the substrate can be a bulk substrate without fins, and the gates can be metal gates or polysilicon gates rather than dummy gates as shown in FIG. 1A.

Besides, in the said embodiment, the first and second doped layers 115 and 121 are made of oxide-based materials with different types of dopants, but the invention is not limited thereto. In another embodiment, the first and second doped layers 115 and 121 can be doped polysilicon layers or doped amorphous silicon layers upon the process requirements.

In summary, in the method of forming doped regions such as source/drain regions of a CMOS device of the invention, the dopant providing layers are formed respectively in N-type and P-type device areas without overlapping with each other, and a single annealing step is performed to drive the dopants into the underlying epitaxial layers. After the drive-in annealing step, the dopant providing layers can be removed simultaneously and uniformly without producing an etching residue due to their similar selectivity against etching. By such manner, the conventional implantation-induced lattice distortion or damage is not observed, and the performance of the device is accordingly improved. Besides, the dopant providing layers can be defined through the existing LDD photomasks without an additional cost, so the competitive advantages can be easily achieved.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

1. A method of forming a semiconductor device, comprising:
providing a substrate having a first area and a second area;
forming a first doped layer containing a first type of dopant on the substrate only in the first area;
forming a second doped layer containing a second type of dopant on the substrate only in the second area;
performing an annealing step to drive the first type of dopant and the second type of dopant into the substrate; and
removing the first and second doped layers simultaneously after the annealing step.

2. The method of claim 1, wherein the step of forming the first doped layer comprises:
forming a first doped material layer containing the first type of dopant on the substrate in the first and second areas;
forming a first mask material layer on the first doped material layer; and
removing the first mask material layer and the first doped material layer in the second area.

3. The method of claim 2, wherein the step of removing the first mask material layer and the first doped material layer in the second area comprises performing first photolithography etching processes.

4. The method of claim 2, wherein the first mask material layer comprises silicon nitride (SiN), silicon carbonitride (SiCN), silicon oxynitride (SiON), silicon carbide (SiC), silicon oxycarbide (SiOC), carbon doped silicon oxynitride (SiOCN) or a combination thereof.

5. The method of claim 1, wherein the step of forming the second doped layer comprises:
forming a second doped material layer containing the second type of dopant on the substrate in the first and second areas;
forming a second mask material layer on the second doped material layer; and
removing the second mask material layer and the second doped material layer in the first area.

6. The method of claim 5, wherein the step of removing the second mask material layer and the second doped material layer comprises performing second photolithography etching processes.

7. The method of claim 5, wherein the second mask material layer comprises SiN, SiCN, SiON, SiC, SiOC, SiOCN or a combination thereof.

8. (canceled)

9. The method of claim 1, wherein the first and second doped layers are defined with lightly doped drain (LDD) photomasks.

10. The method of claim 1, wherein the first and second doped layers have substantially the same thickness.

11. The method of claim 1, wherein the substrate further has first and second gate structures respectively formed in the first and second areas, and the first and second doped layers respectively cover the first and second gate structures.

12. The method of claim 11, wherein the substrate is a substrate having multiple fins extending in a first direction, and the first and second gate structures extend in a second direction different from the first direction.

13. The method of claim 11, wherein the substrate is a bulk substrate.

14. The method of claim 1, wherein the annealing step drives the first type of dopant into first epitaxial layers in the first area and simultaneously drives the second type of dopant into second epitaxial layers in the second area.

15. The method of claim 14, wherein the first epitaxial layers comprise silicon phosphide (SiP) or silicon carbide (SiC), and the second epitaxial layers comprise silicon germanium (SiGe).

16. The method of claim 14, wherein the first epitaxial layers comprise SiGe, and the second epitaxial layers comprise SiP or SiC.

17. The method of claim 1, wherein the first doped layer comprises phosphosilicate glass (PSG) or arsenosilicate glass (ASG), and the second doped layer comprises borophosphosilicate glass (BPSG).

18. The method of claim 1, wherein the first doped layer comprises BPSG, and the second doped layer comprises PSG or ASG.

19. The method of claim 1, wherein the first area is an N-type device area and the second area is a P-type device area.

20. The method of claim 1, wherein the first area is a P-type device area and the second area is an N-type device area.
